(19) United States
(12) Patent Application Publication
(10) Pub. No.: US 2003/0022486 A1
(43) Pub. Date: Jan. 30, 2003

(54) Method for preventing shorts between contact windows and metal lines

(75) Inventor: Joseph Wu, Hsinchu Hsien (TW)

Correspondence Address: Richard P. Berg, Esq., c/o LADAS & PARRY, Suite 2100, 5670 Wilshire Boulevard, Los Angeles, CA, 90036-5679, US

(73) Assignee: ProMOS Technologies Inc.

(21) Appl. No.: 10/097,052

(22) Filed: Mar. 13, 2002

(30) Foreign Application Priority Data
Jul. 25, 2001 (TW) 90118152

(51) Int. Cl. H01L 21/44; H01L 21/4763

(52) U.S. Cl. 438/639; 438/640

(57) ABSTRACT

The present invention provides a method to prevent short of contact and metal lines. The method is applied in a substrate formed with a number of contact windows. The method is comprised of: (a) forming a first conductive layer in the contact windows without filling up the contact windows; (b) forming liners in the contact windows to reduce the openings of the contact windows; (c) forming liner trenches in the contact windows; and (d) forming a second conduction layer on top of the first conductive layer in the contact windows. According to this invention, shorts between contact windows and metal lines is effectively prevented. Therefore, the product yield is greatly improved.

### BACKGROUND OF THE INVENTION

1. Field of the Invention

The present invention relates to a method for preventing shorts in a semiconductor device, particularly to a method for preventing shorts between contact windows and metal lines.

2. Description of the Prior Art

Refer to FIGS. 1A˜1E, which illustrates the top view and cross-section of the conventional method to form contact windows and metal lines. The following explains the background of the prior art.

FIG. 1A shows the top view of the conventional method to form contact windows and metal lines in a semiconductor device. FIG. 1B shows the cross-section along the line A-A′ in FIG. 1A. FIG. 1C shows the cross-section along the line C-C′ in FIG. 1A. Traditionally, in a substrate 100, as shown in in FIG. 1C, a first conductive layer 80 (usually polysilicon plug) fills a contact window 10, formed between two gates 60 with spacers 70. Next, a line trench 20 is formed in a predetermined position. A second conductive layer 40 (usually tungsten) then fills the contact window 10 to form metal line in the line trench 20. In FIGS. 1A˜1C, the contact window 10 is closely located in the vicinity of the metal line 20, consequently, a short between them is easily induced. Moreover, the contact window is usually formed by the SAC (self-aligned contact) method, wherein the shape of the contact window is wide at the top and narrow at the bottom. With the design rule getting smaller and smaller, the wide top part of the contact window can easily cause defects, such as contact or overlap with nearby metal lines, shown as the contact window 10′ drawn in dotted line in FIGS. 1D and 1E, where 20 represents line trench and 80 represents the first conductive layer as described previously. The defect caused degrades the performance of semiconductor devices and has great effect on the production yield.

### SUMMARY OF THE INVENTION

The object of the present invention is to solve the above-mentioned problems and to provide a method for fabricating good quality semiconductor devices without shorts between contact windows and metal lines.

In accordance with the above object, a new method is provided for the prevention of shorts between contact windows and metal lines. The method, applied on a substrate formed with contact windows, comprised of: (a) forming a first conductive layer in the contact windows without filling up the contact windows; (b) forming liners in the contact windows to reduce the openings of the contact windows; (c) forming liner trenches in the contact windows; and (d) forming a second conduction layer on top of the first conductive layer in the contact windows to form contact plugs and metal line respectively. According to the invention, shorts between contact windows and metal lines is effectively prevented.

The present invention is also applicable with a substrate as a startup material. The method is comprised of: providing a silicon substrate formed with gates having spacers; forming an insulation layer covering the gates; forming contact windows, using the spacers as a mask, and exposing the silicon substrate; forming a first conductive layer in the contact windows without filling up the contact windows; forming liners along the insulation layer at two sides of the contact windows and the first conductive layer to reduce the size of opening of the contact window; removing the liners on the insulation layer and at the bottom of the first conductive layer, and remaining the liners on two sidewalls of the contact window; forming metal line trench in the insulation layer; and forming a second conductive layer on the first conductive layer to fill up the contact windows and line trench.

According to the present invention, the distance between contact window and metal line is increased, shown in FIGS. 2A, 2B and 2C, where 15 represents contact window, 25 represents metal line trench, 50 represents liners, 60 represents a gate, 70 represents spacers, and 80 represents a first conductive layer, and 100 represents substrate. Thus, in comparison with prior art shown in FIG. 1A, the size of the contact window 15 is reduced due to the liners 50 formed, consequently, it would not overlap or be in contact with metal line 25. The increase in the distance between the contact window and metal line 25 then contributes to the prevention of shorts between contact windows and metal lines.

### BRIEF DESCRIPTION OF THE DRAWINGS

The present invention will become more fully understood from the detailed preferred embodiment given hereinbelow and the accompanying drawings, given by way of illustration only and thus not intended to be limitative of the present invention.

FIG. 1A shows a schematic top view of the contact window and metal line according to prior art.

FIG. 1B shows a schematic cross-section along the line A-A′ in FIG. 1A.

FIG. 1C shows a schematic cross-section along the line C-C′ in FIG. 1A.

FIG. 1D shows a schematic top view of the contact window and metal line that are not aligned well.

FIG. 1E shows a schematic cross-section along the line A-A′ in FIG. 1D.

FIG. 2A shows a schematic top view of the contact window and metal line according to the present invention.

FIG. 2B shows a schematic cross-section along the line B-B′ in FIG. 2A.

FIG. 2C shows a schematic cross-section along the line D-D′ in FIG. 2A.

FIGS. 3-8 illustrate the cross-sectional diagrams of the process according to the embodiment of the present invention.

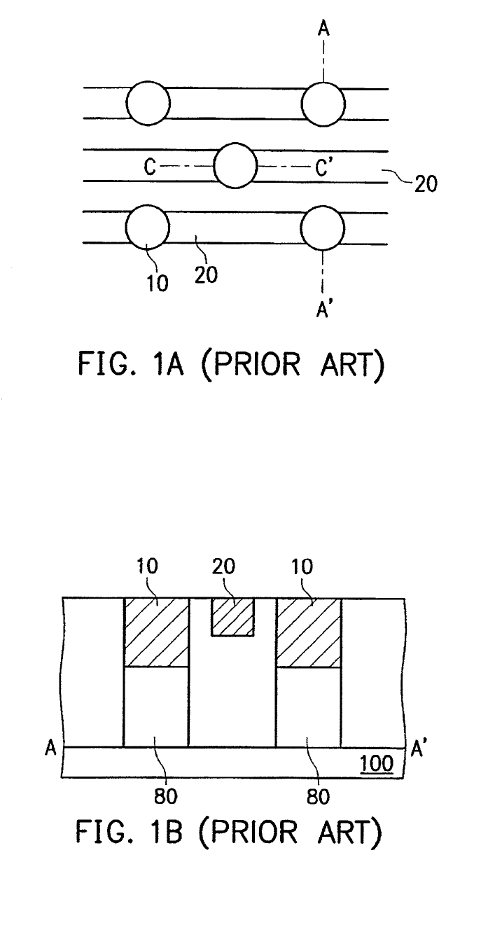

### DETAILED DESCRIPTION OF THE PREFERRED EMBODIMENT

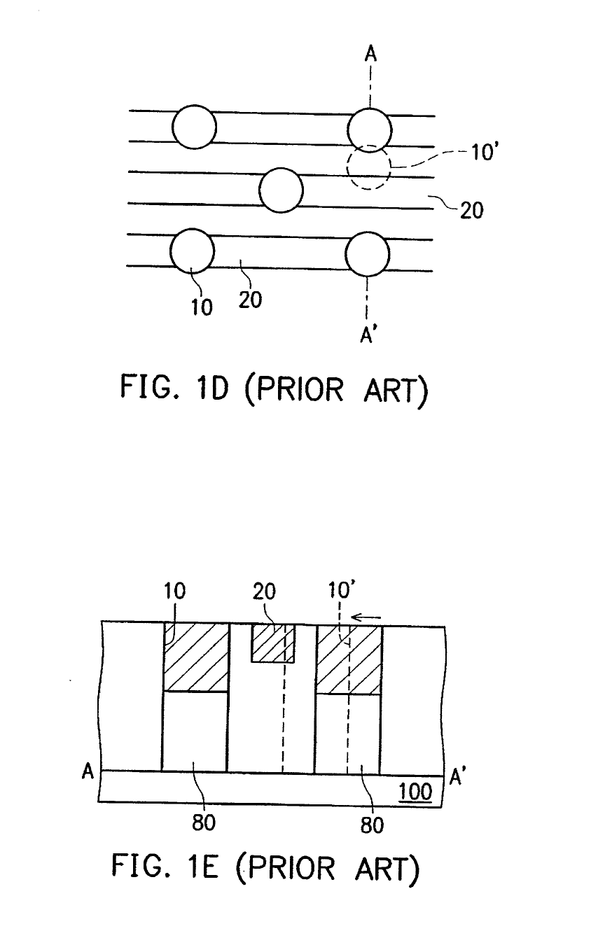

Refer to FIGS. 3˜8, which illustrate the process according to the embodiment of the present invention.

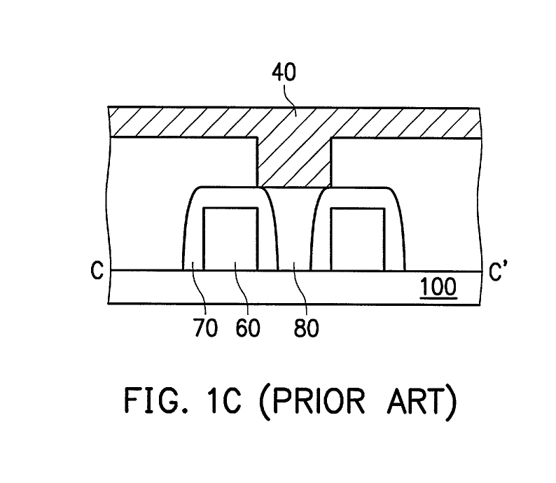

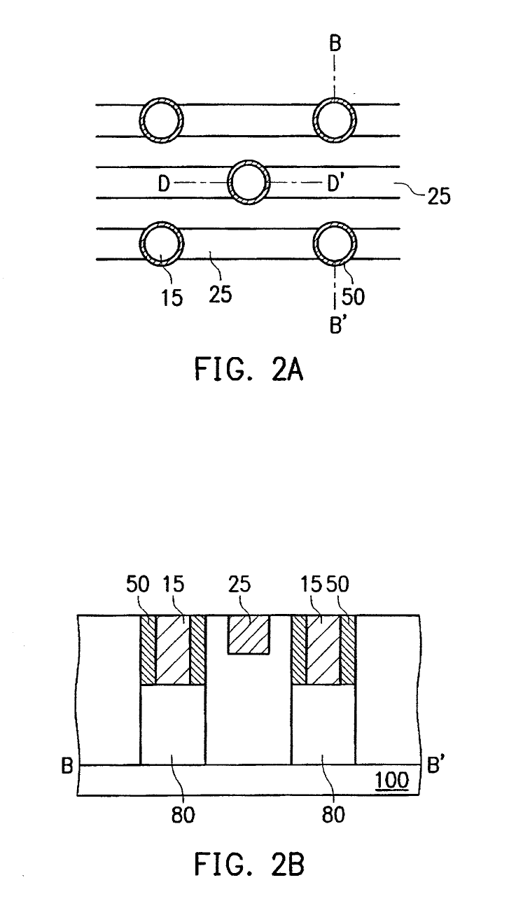

Firstly, as in FIG. 2, a silicon substrate 100 formed with gates 101 having (SiN) spacers 102 is provided. BPSG is then formed over the entire surface of the silicon substrate 100 as an insulation layer 103 to cover the gates 101, spacers 102 and the silicon substrate 100. The spacers are dielectric material selected from Si₃N₄, SiN or SiO₂. Next, as shown in FIG. 4, the insulation layer 103 is etched using the spacers 102 on two sides of the neighbouring gates 101 as etch stopping layer to form a contact window 200 having a wider top part and a narrower bottom part. The size of the wide top part is 0.18 μm, and the size of the narrow bottom part is 0.14 μm and 0.08 μm respectively in FIG. 2B and FIG. 2C. It must be noted that a variation range of ±20% for the size of the contact window is acceptable.

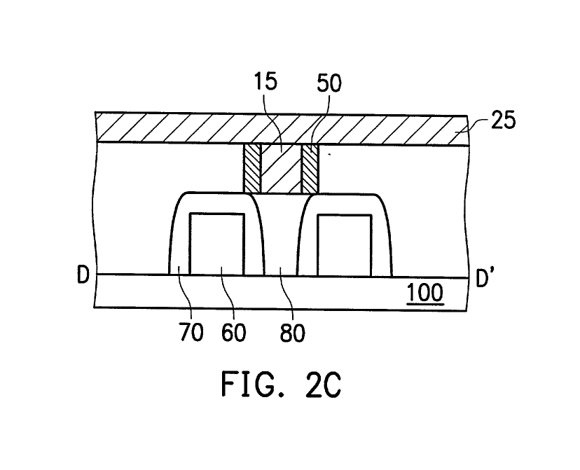

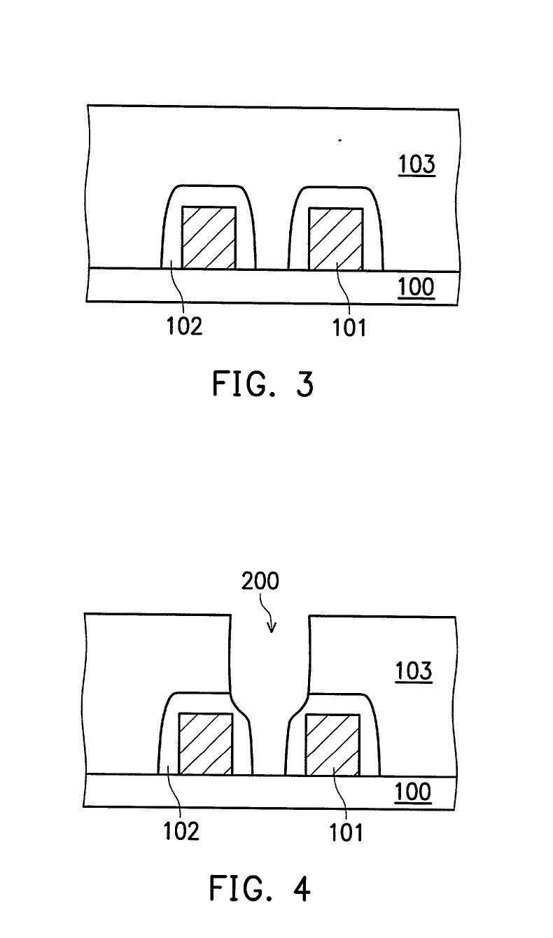

Then, as shown in FIG. 5, the contact window 200 is filled with polysilicon to form a first conductive layer 106 at the bottom part of the contact window 200. Polysilicon is preferrably used as the first conductive layer, however, other conductive material, such as tungsten, may be used as well. At this time, the height of the first conductive layer must be controlled so that it is lower than the depth of the metal line trench formed thereafter to avoid shorts. Next, as shown in FIG. 6, a second insulation layer 107 (SiN) is formed along the sidewalls of the contact window and the first conductive layer 106 to reduce the opening of the contact window. The thickness of the second insulation layer is preferrably 20˜40 nm. The second insulation layer is selected from dielectric material such as oxide or nitride, for example, SiON, SiN or SiO₂. SiN is used in this embodiment.

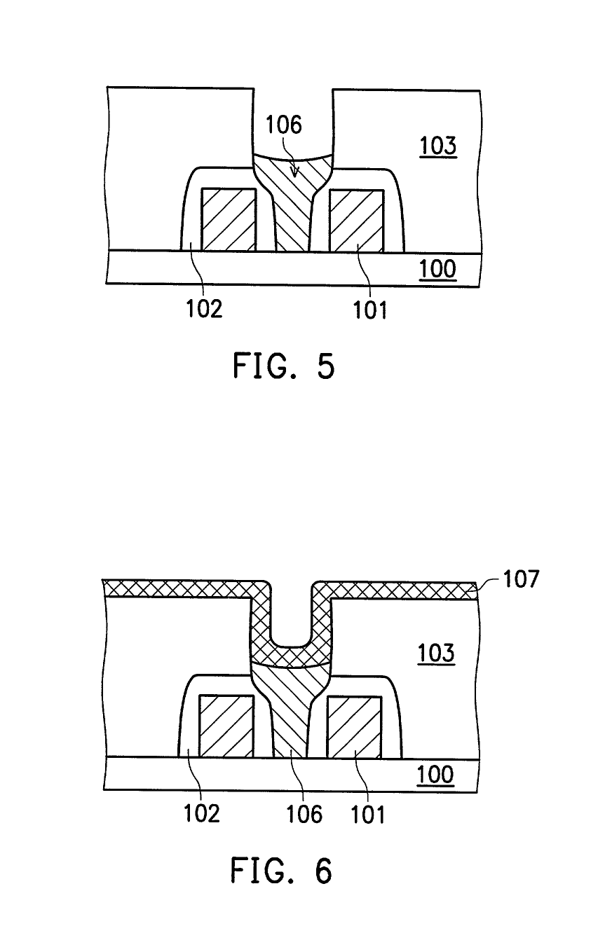

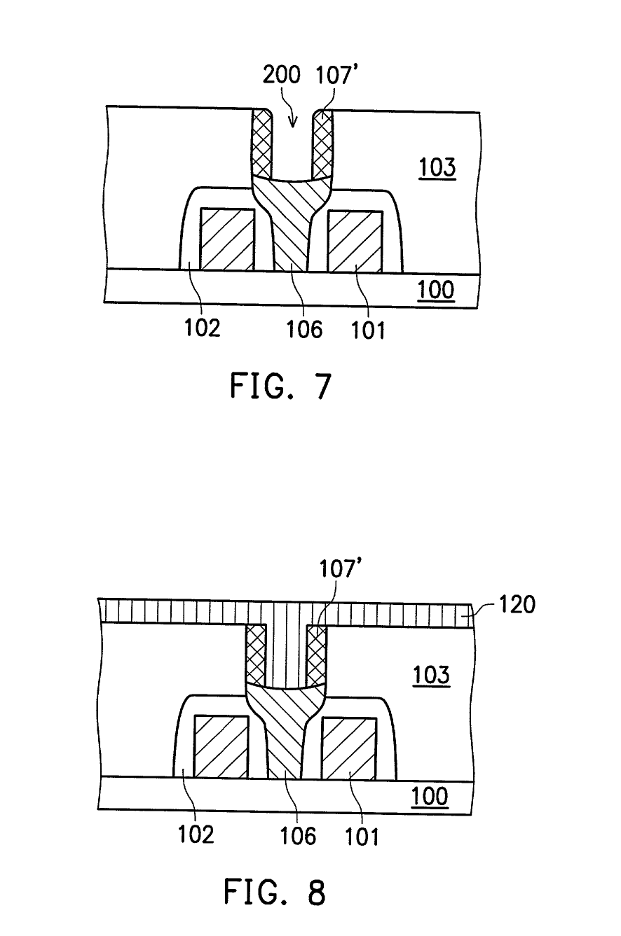

Next, as shown in FIG. 7, the second insulation layer 107 on the insulation layer 103 and at the bottom of the contact window is removed to form liners 107′ on the sidewalls of the contact window 200. A metal line trench (not shown) is then formed in a predetermined position on the insulation layer 103.

Finally, the top part of the contact window and the line trench are filled with tungsten to form a second conductive layer 120 as contact plug and metal line respectively. The second conductive layer and the first conductive layer may be either the same or different material, such as tungsten or polysilicon. However, in the case of manufacturing DRAM, the contact plug formed by the second conductive layer in the contact window is preferrably tungsten, which, because its low dielectric property, creates a better quality bitline.

The foregoing description of the preferred embodiment of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method for preventing shorts between contact and metal line, used in a Si substrate with multiple contact windows, comprising:
(a) forming a first conductive layer in the contact windows without filling up the contact windows;s
(b) forming liners in the contact windows to reduce the size of the contact windows;
(c) forming liner trenches in the contact windows; and
(d) forming a second conduction layer on top of the first conductive layer in the contact windows.

2. A method for preventing shorts between contact and metal line, comprising:
providing a silicon substrate with gates having spacers;
forming an insulation layer covering the gates;
forming contact windows, using the spacers as masks, and exposing the silicon substrate;
forming a first conductive layer in the contact windows without filling up the contact windows;
forming liners along the insulation layer at two sides of the contact and the first conductive layer to reduce the size of the contact;
removing the liners on the insulation layer and at the bottom of the first conductive layer, and leaving the liners on two sidewalls of the contact windows;
forming a metal line trench in the insulation layer; and
forming a second conductive layer on the first conductive layer.

3. The method as claimed in claim 1, wherein the second conductive layer is used as a plug of the contact and metal line of the metal line trench.

4. The method as claimed in claim 2, wherein the second conductive layer is used as plug of the contact and metal line of the metal line trench.

5. The method as claimed in claim 1, wherein the height of the first conductive layer is lower than the depth of the metal line trench.

6. The method as claimed in claim 2, wherein the height of the first conductive layer is lower than the depth of the metal line trench.

7. The method as claimed in claim 1, wherein the thickness of the liners is between 20 and 40 nm.

8. The method as claimed in claim 2, wherein the thickness of the liners is between 20 and 40 nm.

9. The method as claimed in claim 1, wherein the liners are dielectric material.

10. The method as claimed in claim 2, wherein the liners are dielectric material.

11. The method as claimed in claim 9, wherein the dielectric material is selected from the group consisting of SiON, SiN and SiO₂.

12. The method as claimed in claim 10, wherein the dielectric material is selected from the group consisting of SiON, SiN and SiO₂.

13. The method as claimed in claim 1, wherein the spacers are dielectric material.

14. The method as claimed in claim 2, wherein the spacers are dielectric material.

15. The method as claimed in claim 13, wherein the dielectric material is selected from the group consisting of SiON, SIN and SiO₂.

16. The method as claimed in claim 14, wherein the dielectric material is selected from the group consisting of SiON, SiN and SiO₂.

17. The method as claimed in claim 1, wherein the first conductive layer is polysilicon.

18. The method as claimed in claim 2, wherein the first conductive layer is polysilicon.

19. The method as claimed in claim 1, wherein the second conductive layer is selected from the group consisting of tungsten and polysilicon.

20. The method as claimed in claim 2, wherein the second conductive layer is selected from the group consisting of tungsten and polysilicon.
